(19) United States
(12) Patent Application Publication
(10) Pub. No.: US 2026/0173609 A1
(43) Pub. Date: Jun. 18, 2026

(54) DISPLAY DEVICE, METHOD OF MANUFACTURING THE SAME, AND ELECTRONIC DEVICE INCLUDING THE SAME

(71) Applicant: Samsung Display Co., LTD., Yongin-si (KR)

(72) Inventors: Chul Won PARK, Yongin-si (KR); SEONG-JUN CHO, Yongin-si (KR); Kyung-Tae Kim, Yongin-si (KR); Sang Woo SOHN, Yongin-si (KR); Hyunmo Lee, Yongin-si (KR); Jun Hyung LIM, Yongin-si (KR)

(21) Appl. No.: 19/241,861

(22) Filed: Jun. 18, 2025

(30) Foreign Application Priority Data
Dec. 17, 2024 (KR) 10-2024-0189078

(51) Int. Cl. H10H 29/32; H10H 29/01; H10H 29/49

(52) U.S. Cl. CPC H10H 29/32; H10H 29/012; H10H 29/49

(57) ABSTRACT

A display device includes a substrate and a first transistor and a second transistor, which are disposed on the substrate. The first transistor includes a first semiconductor layer, a first lower gate electrode disposed on the first semiconductor layer, a first insulating layer disposed on the first lower gate electrode, and a first upper gate electrode disposed on the first insulating layer. The second transistor includes a second lower gate electrode, a second insulating layer disposed on the second lower gate electrode, a second semiconductor layer disposed on the second insulating layer, and a second upper gate electrode disposed on the second semiconductor layer.

This application claims priority to Korean Patent Application No. 10-2024-0189078, filed on Dec. 17, 2024, and all the benefits accruing therefrom under 35 U.S.C. § 119, the content of which in its entirety is herein incorporated by reference.

### BACKGROUND

### 1. Field

The present disclosure relates to a display device, a method for manufacturing the display device, and an electronic device including the display device.

### 2. Description of the Related Art

A display device is a device for displaying a screen, and may include a liquid crystal display (LCD), an organic light emitting diode (OLED), and the like. A display device may be used in various electronic devices such as a mobile phone, a navigation device, a digital camera, an electronic book, a portable game machine, and various terminals.

The display device may include a plurality of pixels arranged in a row direction and a column direction. Within each pixel, there may be various components such as transistors and capacitors, as well as various wirings capable of supplying signals to the components.

In addition, to manufacture the display device, various electrical elements and conductors such as transistors may be formed by stacking layers of various materials on a substrate and patterning the layers using a method such as an etching process including exposure using a photomask.

These various electrical components, such as transistors and capacitors, are controlled by signals applied at various timings to display images, and the display device may be controlled to emit light of a specific luminance to display the images.

### SUMMARY

Embodiments attempt to provide a display device with improved image quality at low grayscale and a method for manufacturing the same.

In addition, the embodiments attempt to provide an electronic device including a display device with improved image quality at low grayscale.

A display device according to an embodiment includes a substrate, and a first transistor and a second transistor, which are disposed on the substrate. The first transistor includes a first semiconductor layer, a first lower gate electrode disposed on the first semiconductor layer, a first insulating layer disposed on the first lower gate electrode, and a first upper gate electrode disposed on the first insulating layer. The second transistor includes a second lower gate electrode, a second insulating layer disposed on the second lower gate electrode, a second semiconductor layer disposed on the second insulating layer, and a second upper gate electrode disposed on the second semiconductor layer.

The first transistor and the second transistor may be spaced apart from each other, and the first insulating layer and the second insulating layer may be separated from each other.

The display device may further include a first connector electrically connecting the first lower gate electrode and the first upper gate electrode.

The display device may further include a second connector electrically connecting the second lower gate electrode and the second semiconductor layer.

The display device may further include a metal layer disposed between the substrate and the first semiconductor layer and overlapping the first lower gate electrode in a plan view.

A thickness of the first insulating layer from a top surface of the first lower gate electrode and a thickness of the second insulating layer from a top surface of the second lower gate electrode may each be 100 to 1,000 angstroms (Å), and the first lower gate electrode and the second lower gate electrode may each have a thickness of 100 to 2,000 Å.

The first lower gate electrode and the second lower gate electrode may include at least one of molybdenum (Mo) or titanium (Ti).

The first insulating layer and the second insulating layer may include silicon oxide.

The first semiconductor layer and the second semiconductor layer may include different oxide semiconductors.

The display device may further include a first lower gate insulating layer disposed between the first semiconductor layer and the first lower gate electrode, a first upper gate insulating layer disposed between the first insulating layer and the first upper gate electrode, a second lower gate insulating layer disposed between the substrate and the second lower gate electrode, and a second upper gate insulating layer disposed between the second semiconductor layer and the second upper gate electrode.

The first insulating layer and the second insulating layer may be connected to each other.

The display device may further include the first connector electrically connecting the first lower gate electrode and the first upper gate electrode, and the second connector electrically connecting the second lower gate electrode and the second semiconductor layer.

The display device may further include the metal layer disposed between the substrate and the first semiconductor layer and overlapping the first semiconductor layer in a plan view.

A thickness of the first insulating layer from a top surface of the first lower gate electrode and a thickness of the second insulating layer from a top surface of the second lower gate electrode may each be 100 to 1,000 Å, and the first lower gate electrode and the second lower gate electrode may each have a thickness of 100 to 2,000 Å.

An electronic device according to an embodiment includes an electronic component and a display device. The display device includes a substrate, and a first transistor and a second transistor, which are disposed on the substrate. The first transistor includes a first semiconductor layer, a first lower gate electrode disposed on the first semiconductor layer, a first insulating layer disposed on the first lower gate electrode, and a first upper gate electrode disposed on the first insulating layer. The second transistor includes a second lower gate electrode, a second insulating layer disposed on the second lower gate electrode, a second semiconductor layer disposed on the second insulating layer, and a second upper gate electrode disposed on the second semiconductor layer.

According to a method for manufacturing a display device according to an embodiment, a first transistor is formed on a substrate, and a second transistor is formed on the substrate. The forming of the first transistor includes forming a first semiconductor layer on the substrate, forming a first lower gate electrode on the first semiconductor layer, forming a first insulating layer on the first lower gate electrode, and forming a first upper gate electrode on the first insulating layer. The forming of the second transistor includes forming a second lower gate electrode on the substrate, forming a second insulating layer on the second lower gate electrode, forming a second semiconductor layer on the second insulating layer, and forming a second upper gate electrode on the second semiconductor layer.

The first lower gate electrode and the second lower gate electrode may be formed of the same material in the same process, the first insulating layer and the second insulating layer may be formed of the same material in the same process, and the first upper gate electrode and the second upper gate electrode may be formed of the same material in the same process.

Forming the first insulating layer and the second insulating layer may include depositing an insulating material on the first lower gate electrode and the second lower gate electrode to form a preliminary insulating layer, and etching the preliminary insulating layer to form the first insulating layer and the second insulating layer that are separated from each other.

Forming the first insulating layer and the second insulating layer may include depositing an insulating material on the first lower gate electrode and the second lower gate electrode to form the first insulating layer and the second insulating layer which are connected to each other.

The method for manufacturing the display device may further include forming a first connector electrically connecting the first lower gate electrode and the first upper gate electrode, and forming a second connector electrically connecting the second lower gate electrode and the second semiconductor layer.

According to embodiments, an electric field inside a transistor of the display device may be effectively strengthened. Accordingly, the efficiency of voltage control in the semiconductor of the transistor may be effectively improved. Therefore, even with high-efficiency light emission, the image quality at low and high grayscales with transistors may be effectively improved.

Additionally, it is possible to reduce surface resistance inside the transistor of the display device. Accordingly, power consumption may be reduced. Therefore, the power efficiency of the display device may be improved.

According to the embodiments, the manufacturing process of the display device may be simplified. Accordingly, process efficiency in manufacturing the display device may be improved.

Electronic devices according to the embodiments may have improved image quality in high-efficiency light emission and reduced power consumption.

### BRIEF DESCRIPTION OF THE DRAWINGS

FIG. 1 is a schematic top plan view of a display device according to an embodiment.

FIG. 2 is a cross-sectional view of a region corresponding to approximately one pixel included in the display device according to an embodiment.

FIG. 3 is an equivalent circuit diagram of approximately one pixel included in the display device according to an embodiment.

FIGS. 4 to 14 are schematic cross-sectional views illustrating a method for manufacturing the display device according to an embodiment.

FIG. 15 is a cross-sectional view of a region corresponding to approximately one pixel included in the display device according to an embodiment.

FIG. 16 is a graph showing voltage relationships in two different frequency ranges of the display device according to an embodiment.

FIG. 17 is a schematic block diagram of an electronic device according to an embodiment.

FIG. 18 illustrates schematic diagrams showing the electronic device according to different embodiments.

### DETAILED DESCRIPTION

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

Further, since sizes and thicknesses of components shown in the accompanying drawings may be arbitrarily given to facilitate understanding and ease of description, the disclosure is not limited to the illustrated sizes and thicknesses. In the drawings, the thicknesses of layers and regions are exaggerated for clarity. In the drawings, to facilitate understanding and ease of description, the thicknesses of some layers and regions may be exaggerated.

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, being “on” or “above” a reference element, means being positioned above or below the reference element, and it may not necessarily mean being positioned “on” or “above” it in a direction opposite to gravity.

In addition, unless explicitly stated to the contrary, the word “comprise,” and variations such as “comprises” and “comprising,” should be understood to imply the inclusion of stated elements but not the exclusion of any other elements.

In addition, the phrase “on a plane” means a view from a position above the object (e.g., from the top), and the phrase “in a cross-section” means a view of a cross-section of the object which is vertically cut from the side.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

“About” or “substantially equal” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially equal” can mean within one or more standard deviations, or within ±10%, 5% or 2% of the stated value.

Throughout the disclosure, the expression “at least one of a, b or c” indicates only a, only b, only c, both a and b, both a and c, both b and c, all of a, b, and c, or variations thereof.

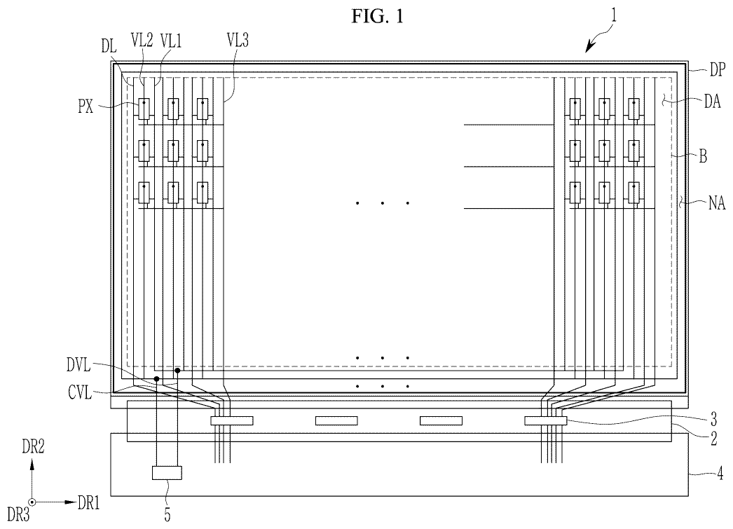

FIG. 1 is a schematic top plan view of a display device according to an embodiment. As used herein, the “plan view” is a view in a thickness direction (third direction DR3) of the display device (or substrate 110).

Referring to FIG. 1, a display device 1 may include a display panel DP, a flexible printed circuit film 2, a driving integrated circuit chip 3, a printed circuit board 4, a power module 5, and the like.

The display panel DP may include a display area DA corresponding to a screen that displays an image, and a non-display area NA in which circuits and wirings for generating and transmitting various signals applied to the display area DA are disposed. The non-display area NA may be adjacent to the display area DA and may surround the display area DA. In FIG. 1, the inner and outer areas of a boundary line B may be the display area DA and the non-display area NA, respectively.

Pixels PX may be arranged in a matrix in the display area DA of the display panel DP. Additionally, a data line DL for transmitting a data voltage, a driving voltage line VL1 for transmitting a driving voltage, a common voltage line VL2 for transmitting a common voltage, and an initialization voltage line VL3 for transmitting an initialization voltage may be positioned in the display area DA. The driving voltage line VL1, the common voltage line VL2, and the initialization voltage line VL3 may extend in a second direction DR2. At least one of the driving voltage line VL1, the common voltage line VL2, or the initialization voltage line VL3 may be connected to an auxiliary voltage line extending in a first direction DR1. Each pixel PX may receive data voltage, driving voltage, common voltage, and initialization voltage from the voltage lines DL, VL1, VL2, and VL3. The driving voltage and common voltage may be power voltages applied to each pixel PX, and the driving voltage line VL1 and the common voltage line VL2 that transmit the power voltages may be referred to as power voltages. The driving voltage may be a higher voltage than the common voltage. The driving voltage may be referred to as a first power voltage or a high-potential power voltage. The common voltage may be referred to as a second power voltage or a low-potential voltage.

In the non-display area NA of the display panel DP, gate drivers (not shown) may be positioned on both sides of the display area DA. The gate driver may be integrated into the non-display area NA. The pixels PX may receive a gate signal (also referred to as a scan signal) generated by the gate driver and receive the data voltage at a predetermined timing.

In the non-display area NA of the display panel DP, a driving voltage transmission line DVL connected to the driving voltage lines VL1 and a common voltage transmission line CVL connected to the common voltage lines VL2 may be positioned. The driving voltage transmission line DVL and the common voltage transmission line CVL may each include portions extending approximately in a second direction y and portions extending approximately in a first direction x. The common voltage transmission line CVL may be positioned to surround the display area DA. The common voltage lines VL2 may be connected to the common voltage transmission lines CVL at the lower and upper sides of the display area DA, thereby supplying a common voltage uniformly across the entire display area DA.

The flexible printed circuit film 2 may have one end connected or bonded to the display panel (DP), and the other end connected or bonded to the printed circuit board 4. The driving integrated circuit chip 3 including a data driver that applies a data voltage to the data line DL may be positioned on the flexible printed circuit film 2.

The power module 5 that generates a power voltage such as a driving voltage or a common voltage may be positioned on the printed circuit board 4. The power module 5 may be provided in the form of an integrated circuit chip. A signal controller (not shown) that controls the data driver and the gate driver may be positioned on the printed circuit board 4.

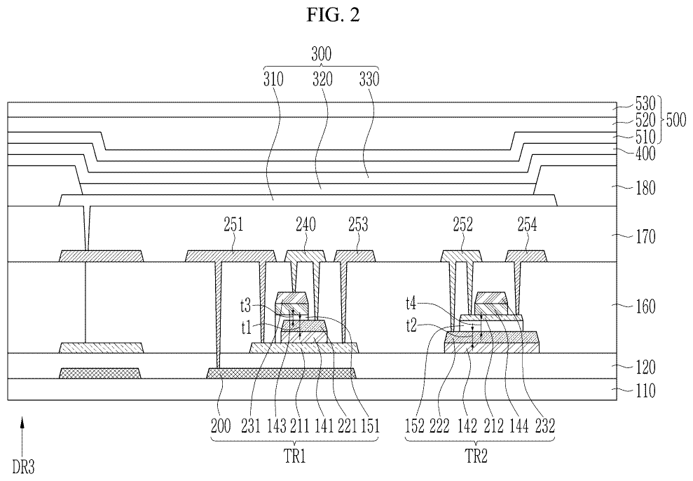

FIG. 2 is a cross-sectional view of a display device according to an embodiment. The cross-section shown in FIG. 2 may correspond to approximately one pixel area.

Referring to FIG. 2, the display device may include a substrate 110, and a first transistor TR1 and a second transistor TR2 positioned on the substrate 110.

The substrate 110 may be a rigid substrate such as a glass substrate. The substrate 110 may be a flexible substrate 110 capable of bending, folding, rolling, or the like. For example, the substrate 110 may include a polymer resin such as polyimide (PI), polyamide (PA), or polyethylene terephthalate (PET). The substrate 110 may be a single-layer structure or a multi-layer structure. The substrate 110 may include at least one base layer including a sequentially formed polymer resin and at least one inorganic layer.

A buffer layer 120 may be positioned on the substrate 110. The buffer layer 120 may flatten the surface of the substrate 110 and block the penetration of impurities into a first semiconductor layer 211 when the first semiconductor layer 211 is formed.

The buffer layer 120 may include an inorganic insulating material such as silicon nitride (SiNₓ), silicon oxide (SiOₓ), or silicon nitride (SiOₓN_{y}), and may be a single-layer structure or a multi-layer structure. The buffer layer (120) may include amorphous silicon (a-Si).

The first transistor TR1 and the second transistor TR2 may be positioned on the substrate 110. The first transistor TR1 and the second transistor TR2 may be positioned in different areas of the substrate 110.

The first transistor TR1 may be provided as a switching transistor. The second transistor TR2 may be provided as a driving transistor. In an embodiment, the first transistor TR1 and the second transistor TR2 may be formed as N-type metal-oxide-semiconductor field-effect transistors (MOSFET). In another embodiment, the first transistor TR1 and the second transistor TR2 may be formed as P-type MOSFETs. In still another embodiment, one of the first transistor TR1 and the second transistor TR2 may be formed as an N-type MOSFET, and the other may be formed as a P-type MOSFET. The first transistor TR1 and the second transistor TR2 may be spaced apart from each other. The first semiconductor layer 211, a first lower gate electrode 221, and a first upper gate electrode 231 included in the first transistor TR1 may be spaced apart from a second semiconductor layer 212, a second lower gate electrode 222, and a second upper gate electrode 232 included in the second transistor TR2, respectively. Additionally, a first lower gate insulating layer 141, a first insulating layer 151, and a first upper gate insulating layer 143 included in the first transistor TR1 may be spaced apart from a second lower gate insulating layer 142, a second insulating layer 152, and a second upper gate insulating layer 144 included in the second transistor TR2, respectively.

The first transistor TR1 may include the first semiconductor layer 211, the first lower gate electrode 221, the first lower gate insulating layer 141, the first insulating layer 151, the first upper gate insulating layer 143, the first upper gate electrode 231, a first electrode 251, and a second electrode 253.

The first semiconductor layer 211 may be positioned on the buffer layer 120. The first semiconductor layer 211 may include an oxide semiconductor. The oxide semiconductor may include at least one of zinc (Zn), indium (In), gallium (Ga), or tin (Sn). For example, the first semiconductor layer 211 may include indium-tin oxide (ITO), indium-gallium-zinc oxide (IGZO), indium-tin-gallium-zinc oxide (ITGZO), or the like. The first semiconductor layer 211 may include a first area, a second area, and a channel area therebetween. One of the first area and the second area may be a source area, and the other may be a drain area. The first semiconductor layer 211 may include amorphous silicon or polycrystalline silicon.

A metal layer 200 may be positioned between the substrate 110 and the first semiconductor layer 211. The metal layer 200 may be referred to as a “light-blocking layer”. The metal layer 200 may be a light-blocking layer that protects the first semiconductor layer 211 of the first transistor TR1 from external light. The metal layer 200 may be positioned to overlap the first semiconductor layer 211 positioned on the upper portion, particularly the channel area, of the first semiconductor layer 211 in a plan view. The metal layer 200 may be covered by the buffer layer 120 at the lower portion of the first semiconductor layer 211. The metal layer 200 may include a metal or metal alloy such as copper (Cu), molybdenum (Mo), aluminum (Al), or titanium (Ti).

The first lower gate insulating layer 141 may be positioned on the first semiconductor layer 211. The first lower gate insulating layer 141 may be positioned to overlap the first semiconductor layer 211 in a plan view. The first lower gate insulating layer 141 is positioned between the first semiconductor layer 211 and the first lower gate electrode 221 to block electrical contact between the first semiconductor layer 211 and the first lower gate electrode 221, thereby preventing a voltage applied to the first lower gate electrode 221 from directly electrically interacting with the first semiconductor layer 211. The first lower gate insulating layer 141 may include an inorganic insulating material such as silicon nitride (SiNₓ), silicon oxide (SiOₓ), or silicon oxynitride (SiOₓN_{y}), and may be a single-layer structure or a multi-layer structure. The first lower gate insulating layer 141 may include an organic insulating material such as polyimide.

The first lower gate electrode 221 of the first transistor TR1 may be positioned on the first lower gate insulating layer 141. The first lower gate electrode 221 may overlap the channel area of the first semiconductor layer 211 in a plan view. The first lower gate electrode 221 may overlap the metal layer 200 in a plan view.

A thickness t1 of the first lower gate electrode 221 may be 2,000 Å or less, about 1,500 Å or less, or about 1,000 Å or less. The thickness t1 of the first lower gate electrode 221 may be the shortest distance between the lower surface and the upper surface of the first lower gate electrode 221 in a third direction DR3, which may be a direction perpendicular to the upper surface of the substrate 110. By forming the first lower gate electrode 221 thinly (2,000 Å or less), the electric field strength may be increased, and the current amount may be improved even with a low gate voltage. Accordingly, the switching speed of the first transistor TR1 utilized as a switching transistor may be improved, and power consumption may be reduced. In addition, even if a first insulating layer 151 described later has a thin thickness, the thickness of the first lower gate electrode 221 may also be formed thinly to prevent the first insulating layer 151 from being damaged. Here, the thickness is measured in the third direction DR3 (thickness direction.) The thickness t1 of the first lower gate electrode 221 may be 100 Å or more, about 300 Å or more, or about 500 Å or more. If the thickness t1 of the first lower gate electrode 221 becomes excessively thin (e.g., less than about 100 Å), cracks may occur in the first lower gate electrode 221 due to fine particles, etc., that may occur during the deposition process of the transistor configuration, and durability may be reduced. By adjusting the thickness of the first lower gate electrode 221 within the above-mentioned range, the durability of the first lower gate electrode may be improved, while the switching speed of the first transistor TR1 may be improved.

The first lower gate electrode 221 may include a metal or metal alloy such as copper (Cu), molybdenum (Mo), aluminum (Al), silver (Ag), chromium (Cr), tantalum (Ta), or titanium (Ti), and may be a single-layer structure or a multi-layer structure. In an embodiment, the first lower gate electrode 221 may be a single-layer structure or a two-layer structure including at least one of molybdenum (Mo) or titanium (Ti). Accordingly, the adhesion characteristics of the first lower gate electrode 221 may be improved, and even if the first lower gate electrode 221 is formed thinly, the electrical stability of the first transistor TR1 may be improved.

The first insulating layer 151 may be positioned on the first lower gate electrode 221. The first insulating layer 151 may include an inorganic insulating material such as silicon nitride (SiNₓ), silicon oxide (SiOₓ), or silicon oxynitride (SiOₓN_{y})

The first insulating layer 151 may be a single-layer structure or a multi-layer structure. In an embodiment, the first insulating layer 151 may be a silicon oxide (SiOₓ) layer with a two-layer structure or less. By forming the first insulating layer 151 into a two-layer structure or less, the thickness of the first insulating layer 151 may be reduced. In addition, since silicon oxide is included in the first insulating layer 151, the electric field effect occurring in the first transistor TR1 may be improved.

A thickness t3 of the first insulating layer 151 may be 1,000 Å or less, about 900 Å or less, or about 800 Å or less. The thickness t3 of the first insulating layer 151 may be the shortest distance between the lower surface and the upper surface of the first insulating layer 151 in the third direction DR3, which may be a direction perpendicular to the upper surface of the substrate 110. That is, thickness t3 of the first insulating layer 151 may be a thickness from a top surface of the first lower gate electrode 221 to a bottom surface of the first upper gate insulating layer 143. The thickness t3 of the first insulating layer 151 is formed thinly (1,000 Å or less), so that the overall thickness of the first transistor TR1 may be reduced.

The thickness t3 of the first insulating layer 151 may be 100 Å or more, about 200 Å or more, or about 300 Å or more. By forming the thickness t3 of the first insulating layer 151 to be greater than or equal to the above thickness range (e.g., at least 100 Å), it is possible to prevent damage to the first insulating layer 151 caused by fine particles, etc., and suppress electrical leakage current.

The first upper gate insulating layer 143 may be positioned on the first insulating layer 151. The first upper gate insulating layer 143 is positioned on the first insulating layer 151 so that heat generation between the first lower gate electrode 221 and the first upper gate electrode 231 may be suppressed by the thin thickness of the first insulating layer 151.

The first upper gate insulating layer 143 may include an inorganic insulating material such as silicon nitride (SiNₓ), silicon oxide (SiOₓ), or silicon oxynitride (SiOₓN_{y}), and may be a single-layer structure or a multi-layer structure. The first upper gate insulating layer 143 may include an organic insulating material such as polyimide.

The first upper gate electrode 231 may be positioned on the first upper gate insulating layer 143. The first upper gate electrode 231 may include a metal alloy such as copper (Cu), molybdenum (Mo), aluminum (Al), silver (Ag), chromium (Cr), tantalum (Ta), titanium (Ti), etc., and may be a single-layer structure or a multi-layer structure.

The first upper gate electrode 231 may be electrically connected to the first lower gate electrode 221. For example, the first lower gate electrode 221 and the first upper gate electrode 231 may be electrically connected through a connector 240. The connector 240 that electrically connects the first upper gate electrode 231 and the first lower gate electrode 221 may be referred to as a “first connector”. The first lower gate electrode 221 is formed with a thin thickness and may have high surface resistance. Heat may be generated in the first lower gate electrode 221 due to high surface resistance, and the durability of the first transistor TR1 may be deteriorated when the connector 240 does not exist. However, in an embodiment, since the first lower gate electrode 221 is connected to the first upper gate electrode 231 through the connector 240, current may also flow to the first upper gate electrode 231, thus compensating for the high surface resistance of the first lower gate electrode 221.

The second transistor TR2 may include the second lower gate electrode 222, the second lower gate insulating layer 142, the second insulating layer 152, the second upper gate insulating layer 144, the second semiconductor layer 212, the second upper gate electrode 232, a first electrode 252, and a second electrode 254. Hereinafter, the first electrode 252 of the second transistor TR2 may be referred to as a “second connector”.

The second lower gate insulating layer 142 may be positioned on the buffer layer 120. The second lower gate insulating layer 142 may be positioned to overlap the second semiconductor layer 212 in a plan view. The second lower gate insulating layer 142 may include or be formed of the same material as the first lower gate insulating layer 141. For example, the second lower gate insulating layer 142 may include an inorganic insulating material such as silicon nitride (SiNₓ), silicon oxide (SiOₓ), or silicon oxynitride (SiOₓN_{y}), and may be a single-layer structure or a multi-layer structure. The second lower gate insulating layer 142 may include an organic insulating material such as polyimide. The second lower gate electrode 222 may be positioned on the second lower gate insulating layer 142. An electric field formed in the second semiconductor layer 212 by the second lower gate electrode 222 may increase, and the electrical conductivity and current of the second semiconductor layer 212 may increase. Accordingly, the current of the second semiconductor layer 212 may be precisely controlled with a low-potential voltage, so that the brightness of a light emitting layer may be precisely controlled and noise may be reduced. Therefore, the image quality at low grayscale may be improved.

A thickness t2 of the second lower gate electrode 222 may be 2,000 Å or less, about 1,500 Å or less, or about 1,000 Å or less. The thickness t2 of the second lower gate electrode 222 may be the shortest distance between the lower surface and the upper surface of the second lower gate electrode 222 in the third direction DR3, which may be a direction perpendicular to the upper surface of the substrate 110. By forming the second lower gate electrode 222 thinly (e.g., 2,000 Å or less), the electric field strength formed in the second semiconductor layer 212 may be increased. Accordingly, the driving current amplification performance of the second transistor TR2 used as a driving transistor may be improved, and a low delay time may be achieved. Furthermore, even if the second insulating layer 152 has a thin thickness, the thickness of the second lower gate electrode 222 may also be formed thin to prevent the second insulating layer 152 from being damaged.

The thickness t2 of the second lower gate electrode 222 may be 100 Å or more, about 300 Å or more, or about 500 Å or more. If the thickness t2 of the second lower gate electrode 222 becomes excessively thin (e.g., less than 100 Å), cracks may occur in the second lower gate electrode 222 due to fine particles, etc., that may occur during the deposition process of the transistor configuration, and durability may be reduced. By adjusting the thickness of the second lower gate electrode 222 within the above-mentioned range, the durability of the second lower gate electrode may be improved.

The second lower gate electrode 222 may include or be formed of the same material as the first lower gate electrode 221. For example, the second lower gate electrode 222 may include at least one of molybdenum (Mo) or titanium (Ti). Accordingly, the bonding strength of the second lower gate electrode 222 may be improved, and even if the second lower gate electrode 222 is formed thinly, the electric field characteristics of the first transistor TR1 may be improved.

The second insulating layer 152 may be positioned on the second lower gate electrode 222. The second insulating layer 152 may be separated from the first insulating layer 151, and may be spaced apart from each other. Accordingly, the thin thickness of the first insulating layer 151 and the second insulating layer 152 may prevent the first insulating layer 151 and the second insulating layer 152 from being disconnected while the transistors TR1 and TR2 are being driven. Therefore, heat generated in the first insulating layer 151 and the second insulating layer 152 may be suppressed from being transferred to other components, and the durability of the transistors TR1 and TR2 may be improved.

The second insulating layer 152 may include or be formed of the same material as the first insulating layer 151. For example, the second insulating layer 152 may be a silicon oxide (SiOₓ) layer with a two-layer structure or less. By forming the second insulating layer 152 thinly, the electric field effect through the second insulating layer 152 may increase. Accordingly, the current may be finely controlled through low-potential voltage, thereby improving brightness and color reproducibility. Therefore, the image quality at low grayscale may be improved.

A thickness t4 of the second insulating layer 152 may be 1,000 Å or less, about 900 Å or less, or about 800 Å or less. The thickness t4 of the second insulating layer 152 may be the shortest distance between the lower surface and the upper surface of the first lower gate electrode 221 in the third direction DR3, which may be a direction perpendicular to the upper surface of the substrate 110. The thickness t4 of the second insulating layer 152 is formed thinly (1,000 Å or less), so the size of the second transistor TR2 may be reduced, and the efficiency of the second transistor TR2 may be improved by reducing the on-resistance.

The thickness t4 of the second insulating layer 152 may be 100 Å or more, about 200 Å or more, or about 300 Å or more. By forming the thickness t4 of the second insulating layer 152 to be greater than or equal to the above thickness range (e.g., at least 100 Å), it is possible to prevent damage to the second insulating layer 152 caused by fine particles, etc., and thus reduce the difficulty of the deposition process of the second insulating layer 152.

The second semiconductor layer 212 may be positioned on the second insulating layer 152. The second semiconductor layer 212 may include an oxide semiconductor. The oxide semiconductor may include at least one of zinc (Zn), indium (In), gallium (Ga), or tin (Sn). For example, the second semiconductor layer 212 may include indium-tin oxide (ITO), indium-gallium-zinc oxide (IGZO), indium-tin-gallium-zinc oxide (ITGZO), or the like. The second semiconductor layer 212 may include the first area, the second area, and the channel area therebetween. One of the first area and the second area may be a source area, and the other may be a drain area. The second semiconductor layer 212 may include either amorphous silicon or polycrystalline silicon.

The first semiconductor layer 211 and the second semiconductor layer 212 may include different oxide semiconductors. The first transistor TR1 may be provided as a switching transistor, and the first semiconductor layer 211 may include copper oxide (CuO), titanium oxide (TiO₂), indium-tin-gallium-zinc oxide (ITGZO), or the like that can withstand high voltage and current. The second transistor TR2 may be provided as a driving transistor, and the second semiconductor layer 212 may include indium-tin oxide (ITO), zinc oxide (ZnO), indium-gallium-zinc oxide (IGZO), or the like with high electron mobility. Since the first semiconductor layer 211 and the second semiconductor layer 212 include different oxide semiconductors, the characteristics of the first transistor TR1 and the second transistor TR2, which are provided as a switching transistor and a driving transistor respectively, may be improved.

The second semiconductor layer 212 may be electrically connected to the second lower gate electrode 222. For example, the second lower gate electrode 222 and the second semiconductor layer 212 may be electrically connected by the first electrode 252. The second lower gate electrode 222 may be formed with a thin thickness and have high surface resistance. However, since the second lower gate electrode 222 is electrically connected to the second semiconductor layer 212 through the first electrode 252 of the second transistor TR2, some of the current applied to the second lower gate electrode 222 may flow to the second semiconductor layer 212. Accordingly, the high surface resistance of the second lower gate electrode 222 may be compensated for through the second semiconductor layer 212 electrically connected through the first electrode 252.

The second upper gate insulating layer 144 may be positioned on the second semiconductor layer 212. The second upper gate insulating layer 144 may include or be formed of the same material as the first upper gate insulating layer 143. For example, the second upper gate insulating layer 144 may include an inorganic insulating material such as silicon nitride (SiNₓ), silicon oxide (SiOₓ), or silicon oxynitride (SiOₓN_{y}), and may be a single-layer structure or a multi-layer structure. The first upper gate insulating layer 143 may include an organic insulating material such as polyimide.

The second upper gate electrode 232 may be positioned on the second upper gate insulating layer 144. The second upper gate electrode 232 may include or be formed of the same material as the first upper gate electrode 231. For example, the second upper gate electrode 232 may include a metal alloy such as copper (Cu), molybdenum (Mo), aluminum (Al), silver (Ag), chromium (Cr), tantalum (Ta), titanium (Ti), etc., and may be a single-layer structure or a multi-layer structure.

An interlayer-insulating layer 160 may be positioned on the first upper gate electrode 231 and the second upper gate electrode 232. The interlayer-insulating layer 160 may include an inorganic insulating material such as silicon nitride (SiNₓ), silicon oxide (SiOₓ), or silicon oxynitride (SiOₓN_{y}), and may be a single-layer structure or a multi-layer structure. The interlayer-insulating layer 160 may include an organic insulating material such as polyimide.

A conductive layer including the first and second electrodes 251 and 253 of the first transistor TR1 and the first and second electrodes 252 and 254 of the second transistor TR2 may be positioned on the interlayer-insulating layer 160. The conductive layer may further include the connector 240. The conductive layer may include aluminum (Al), platinum (Pt), silver (Ag), magnesium (Mg), gold (Ag), nickel (Ni), neodymium (Nd), iridium (Ir), chromium (Cr), calcium (Ca), molybdenum (Mo), titanium (Ti), tungsten (W), copper (Cu), or the like, and may be a single-layer structure or a multi-layer structure.

The first electrode 251 and the second electrode 253 of the first transistor TR1 may be connected to the first area and the second area of the first semiconductor layer 211 through contact holes formed in the interlayer-insulating layer 160. One of the first electrode 251 and the second electrode 253 may be a source electrode, and the other may be a drain electrode. The first electrode 251 may be connected to the metal layer 200 through a contact hole formed in the interlayer-insulating layer 160, and thus the first electrode 251 may electrically connect the metal layer 200 and the first semiconductor layer 211. The connector 240 may electrically connect the first lower gate electrode 221 and the first upper gate electrode 231 through a contact hole formed in the interlayer-insulating layer 160. Accordingly, the first semiconductor layer 211, the first lower gate electrode 221, the first upper gate electrode 231, the connector 240, the first electrode 251, and the second electrode 253 may be included in one first transistor TR1.

The first electrode 252 and the second electrode 254 of the second transistor TR2 may be connected to the first area and the second area of the second semiconductor layer 212 through a contact hole formed in the interlayer-insulating layer 160. One of the first electrode 252 and the second electrode 254 may be a source electrode, and the other may be a drain electrode. The first electrode 252 may be connected to the second lower gate electrode 222 through a contact hole formed in the interlayer-insulating layer 160, and thus the first electrode 252 may electrically connect the second lower gate electrode 222 and the second semiconductor layer 212. Accordingly, the second semiconductor layer 212, the second lower gate electrode 222, the second upper gate electrode 232, the first electrode 252, and the second electrode 254 may be included in one second transistor TR2.

A planarization layer 170 may be positioned on the first transistor TR1 and the second transistor TR2. The planarization layer 170 may include an organic insulating material such as a general-purpose polymer such as poly(methyl methacrylate) or polystyrene, a polymer derivative having a phenol group, an acrylic polymer, an imide polymer (e.g., polyimide), or a siloxane polymer.

A lower electrode 310 of a light emitting device 300 may be positioned on the planarization layer 170. The lower electrode 310 of the light emitting device 300 may be referred to as a pixel electrode. The lower electrode 310 may include a transparent conductive material such as indium-tin oxide (ITO) or indium-zinc oxide (IZO). The lower electrode 310 may include a metal or metal alloy such as lithium (Li), calcium (Ca), aluminum (Al), silver (Ag), magnesium (Mg), or gold (Au). The lower electrode 310 of the light emitting device 300 may be connected to at least one of the first electrode 251 or the second electrode 253 of the first transistor TR1, and the first electrode 252 and the second electrode 254 of the second transistor TR2 through the contact hole of the planarization layer 170. Accordingly, the lower electrode 310 may be electrically connected to the transistors TR1 and TR2 to receive a driving current that controls the luminance of a light emitting diode.

A pixel definition layer 180 may be positioned on the edge of the lower electrode 310 and the planarization layer 170. The pixel definition layer 180 may be referred to as a bank or a barrier rib, and may include a pixel opening that overlaps at least a portion of the lower electrode 310 in a plan view. The pixel definition layer 180 may include an organic insulating material such as a general-purpose polymer such as polymethyl methacrylate or polystyrene, a polymer derivative having a phenol group, an acrylic polymer, an imide polymer, or a siloxane polymer. The pixel definition layer 180 may include an inorganic insulating material such as silicon nitride (SiNₓ), silicon oxide (SiOₓ), or silicon oxynitride (SiOₓN_{y}).

A light emitting layer 320 of the light emitting device 300 may be positioned on the lower electrode 310. The light emitting layer 320 may include at least one of an organic material or an inorganic material. In addition to the light emitting layer 320, a functional layer (not shown) including at least one of a hole injection layer, a hole transport layer, an electron transport layer, or an electron injection layer may be positioned on the lower electrode 310.

An upper electrode 330 of the light emitting device 300 may be positioned on the light emitting layer 320. The upper electrode 330 of the light emitting device 300 may be referred to as a common electrode. The upper electrode 330 may be made light transmissive by forming a thin layer of a metal or metal alloy with a low work function, such as calcium (Ca), barium (Ba), magnesium (Mg), aluminum (Al), or silver (Ag). The upper electrode 330 may include a transparent conductive oxide such as indium-tin oxide (ITO) or indium-zinc oxide (IZO).

The lower electrode 310, the light emitting layer 320, and the upper electrode 330 of each pixel may form the light emitting device 300 such as an organic light emitting diode. The lower electrode 310 of the light emitting device 300 may be an anode, which is a hole injection electrode, and the upper electrode 330 may be a cathode, which is an electron injection electrode. Light emission may occur when holes and electrons are injected into the light emitting layer 320 from the lower electrode 310 and the upper electrode 330, respectively, and excitons formed by combining the injected holes and electrons drop from the excited state to the ground state. Depending on the driving method of the display device, the anode and cathode electrodes may be formed in reverse.

A capping layer 400 may be positioned on the light emitting device 300. The capping layer 400 may improve light efficiency by adjusting a refractive index.

An encapsulating layer 500 may be positioned on the capping layer 400. The encapsulating layer 500 may encapsulate the light emitting device 300 including the light emitting layer 320 to prevent moisture or oxygen from penetrating from the outside. The encapsulating layer 500 may be a thin film encapsulating layer including one or more inorganic layers 510 and 530 and one or more organic layers 520.

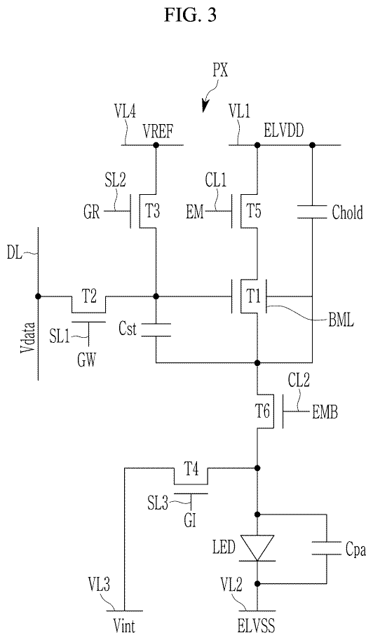

FIG. 3 is an equivalent circuit diagram of one pixel included in the display device according to an embodiment.

Referring to FIG. 3, the pixel PX may include a plurality of transistors T1, T2, T3, T4, T5, and T6, a storage capacitor Cst, a hold capacitor Chold, a parasitic capacitor Cpa, and a light emitting diode LED connected to multiple wirings. Circuit transistors and capacitors, except for the light emitting diodes LED, form a pixel circuit so that one pixel PX may be divided into the pixel circuit and the light emitting diode LED. At least one of the plurality of transistors T1, T2, T3, T4, T5, and T6 may be an n-type transistor.

One pixel may have a plurality of wirings VL1, VL2, VL3, VL4, SL1, SL2, SL3, CL1, CL2, and DL connected to it. The plurality of wirings may include the driving voltage line VL1, the common voltage line VL2, the initialization voltage line VL3, a reference voltage line VL4, the data line DL, a first scan line SL1, a second scan line SL2, a third scan line SL3, a first light emitting control line CL1, and a second light emitting control line CL2.

The first scan line SL1 may transmit a first scan signal GW to the gate electrode of a second circuit transistor T2. The second scan line SL2 may transmit a second scan signal GR to the gate electrode of a third circuit transistor T3. The third scan line SL3 may transmit a third scan signal GI to the gate electrode of a fourth circuit transistor T4.

The first light emitting control line CL1 may transmit a first light emitting signal EM to the gate electrode of a fifth circuit transistor T5. The second light emitting control line CL2 may transmit a second light emitting signal EMB to the gate electrode of a sixth circuit transistor T6.

The data line DL may transmit a data voltage Vdata generated by a data driver (not shown). Accordingly, the size of the light emitting current transmitted to the light emitting diode LED may change, thereby changing the luminance emitted by the light emitting diode LED. The driving voltage line VL1 may apply a driving voltage ELVDD. The common voltage line VL2 may transmit a driving low-voltage ELVSS from one side of the light emitting diode LED.

The initialization voltage line VL3 may transmit an initialization voltage Vint. A reference voltage line VL4 may transmit a reference voltage VREF. The voltages applied to the driving voltage line VL1, the common voltage line VL2, the initialization voltage line VL3, and the reference voltage line VL4 may each be a constant voltage.

The plurality of transistors T1, T2, T3, T4, T5, and T6 may include a first circuit transistor T1, a second circuit transistor T2, a third circuit transistor T3, a fourth circuit transistor T4, a fifth circuit transistor T5, and a sixth circuit transistor T6.

The first circuit transistor T1 may be an n-type transistor and may include an oxide semiconductor as a semiconductor layer. The first circuit transistor T1 may be referred to as a driving transistor. The size of the light emitting current output to one electrode (e.g., the anode) of the light emitting diode LED may be controlled depending on the size of the voltage of the gate electrode of the first circuit transistor T1 (e.g., the voltage stored in the storage capacitor Cst). The size of the light emitting current output to the light emitting diode LED may be adjusted according to the data voltage Vdata applied to the pixel PX.

The first circuit transistor T1 is disposed to receive the driving voltage ELVDD and may be connected to the driving voltage line VL1 via the fifth circuit transistor T5. The first circuit transistor T1 may output light emitting current to the sixth circuit transistor T6 and may be connected to the sixth circuit transistor. The data voltage Vdata may be applied to the gate electrode of the first circuit transistor T1 through the second circuit transistor T2.

The gate electrode of the first circuit transistor T1 may be connected to the storage capacitor Cst. The voltage of the gate electrode of the first circuit transistor T1 may change depending on the voltage stored in the storage capacitor Cst, and accordingly, the light emitting current output by the first circuit transistor T1 may change. The storage capacitor Cst may keep the voltage of the gate electrode of the first circuit transistor T1 constant during one frame. The gate electrode of the first transistor T1 is connected to the third circuit transistor T3, which may be initialized by receiving the reference voltage VREF.

The first circuit transistor T1 may further include an overlapping electrode BML overlapping a channel of the semiconductor layer in a plan view, and the overlapping electrode BML may be connected to the sixth circuit transistor T6, the storage capacitor Cst, and the hold capacitor Chold. The metal layer 200 described with reference to FIG. 2 may be provided as the overlapping electrode BML in a plan view.

The second circuit transistor T2 may be an n-type transistor and may include an oxide semiconductor as a semiconductor layer. The second circuit transistor T2 may be a transistor that receives the data voltage Vdata into the pixel PX. The gate electrode of the second circuit transistor T2 may be connected to the first scan line SL1. One electrode of the second circuit transistor T2 may be connected to the data line DL, and the other electrode of the second circuit transistor T2 may be connected to the first circuit transistor T1, the third circuit transistor T3, and the storage capacitor Cst. When the second circuit transistor T2 is turned on by the voltage of the first scan signal GW transmitted through the first scan line SL1, the data voltage Vdata transmitted through the data line DL may be transmitted to the gate electrode of the first circuit transistor T1, and the data voltage Vdata may be stored in the storage capacitor Cst.

The third circuit transistor T3 may be an n-type transistor and may include an oxide semiconductor as a semiconductor layer. The third circuit transistor T3 may transmit the reference voltage VREF to the first circuit transistor T1 and the storage capacitor Cst. The gate electrode of the third circuit transistor T3 may be connected to the second scan line SL2, and one electrode of the third circuit transistor T3 may be connected to the reference voltage line VL4. The other electrode of the third circuit transistor T3 may be connected to the storage capacitor Cst, the gate electrode of the first circuit transistor T1, and the second circuit transistor T2. The third circuit transistor T3 may be turned on by the voltage of the second scan signal GR received through the second scan line SL2, and may be initialized by transmitting the reference voltage VREF to the first circuit transistor T1 and the storage capacitor Cst.

The fourth circuit transistor T4 may be an n-type transistor and may include an oxide semiconductor as a semiconductor layer. The fourth circuit transistor T4 may initialize the light emitting diode LED. When the fourth circuit transistor T4 initializes the light emitting diode LED, it may also initialize the sixth circuit transistor T6 and the parasitic capacitor Cpa. The gate electrode of the fourth circuit transistor T4 may be connected to the third scan line SL3, and one electrode of the fourth circuit transistor T4 may be connected to the light emitting diode LED, the sixth circuit transistor T6, and the parasitic capacitor Cpa. One electrode of the fourth circuit transistor T4 may be connected to the initialization voltage line VL3. When the fourth circuit transistor T4 is turned on by the voltage of the third scan signal SL3 flowing through the third scan line SL3, the initialization voltage Vint may be applied to the light emitting diode LED, the sixth circuit transistor T6, and the parasitic capacitor Cpa for initialization.

The fifth circuit transistor T5 may be an n-type transistor and may have an oxide semiconductor as a semiconductor layer. The fifth circuit transistor T5 may transmit the driving voltage ELVDD to the first circuit transistor T1. The gate electrode of the fifth circuit transistor T5 may be connected to the first light emitting control line CL1, one electrode of the fifth circuit transistor T5 may be connected to a driving voltage line 172, and the other electrode of the fifth circuit transistor T5 may be connected to the first circuit transistor T1. When the fifth circuit transistor T5 is turned on by the voltage of the first emitting signal EM flowing through the first emitting control line CL1, the driving voltage ELVDD may be applied to the first circuit transistor T1.

The sixth circuit transistor T6 may be an n-type transistor and may include an oxide semiconductor as a semiconductor layer. The gate electrode of the sixth circuit transistor T6 may be connected to the second light emitting control line CL2. One electrode of the sixth transistor T6 may be connected to the fourth circuit transistor T4. When the sixth circuit transistor T6 is turned on by the voltage of the second light emitting signal EMB flowing through the second light emitting control line CL2, the driving current output from the first circuit transistor T1 may be applied to the light emitting diode LED. The sixth circuit transistor T6 may be referred to as a light emitting transistor.

The first transistor TR1 described with reference to FIG. 2 may correspond to the first pixel transistor T1, and the second transistor TR2 may correspond to any one of the second to sixth transistors T2, T3, T4, T5, and T6.

One electrode of the storage capacitor Cst may be connected to the first circuit transistor T1, the fourth circuit transistor T4, the sixth circuit transistor T6, and the hold capacitor Chold. The storage capacitor Cst may keep the voltage of the gate electrode of the first circuit transistor T1 constant during one frame.

One electrode of the hold capacitor Chold may be connected to the driving voltage line VL1, and the other electrode of the hold capacitor Chold may be connected to the first circuit transistor T1, the fourth circuit transistor T4, the sixth circuit transistor T6, and the storage capacitor Cst. The hold capacitor Chold may keep the voltage of the first circuit transistor T1 and the sixth circuit transistor T6 constant.

One electrode of the parasitic capacitor Cpa may be connected to the common voltage line VL2, and the other electrode of the parasitic capacitor Cpa may be connected to the fourth transistor T4 and the sixth circuit transistor T6.

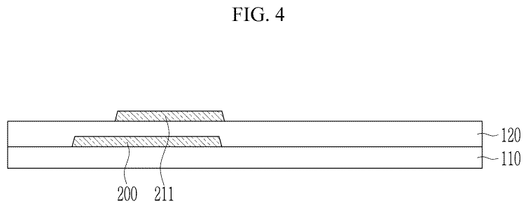

Hereinafter, with reference to FIGS. 4 to 14, a method for manufacturing the lower portion of the planarization layer 170 of the display device shown in FIG. 2 (hereinafter referred to as a backplane) will be described. A backplane of the display device may be manufactured by forming the first transistor TR1 on the substrate 110 and forming the second transistor TR2 on the substrate 110.

The first transistor TR1 of the backplane may be manufactured by forming the first semiconductor layer 211 on the substrate 110, forming the first lower gate electrode 221 on the first semiconductor layer 211, forming the first insulating layer 151 on the first lower gate electrode 221, and forming the first upper gate electrode 231 on the first insulating layer 151.

The second transistor TR2 of the backplane may be manufactured by forming the second lower gate electrode 222 on the substrate 110, forming the second insulating layer 152 on the second lower gate electrode 222, forming the second semiconductor layer 212 on the second insulating layer 152, and forming the second upper gate electrode 232 on the second semiconductor layer 212.

FIGS. 4 to 14 are schematic cross-sectional views illustrating a method for manufacturing a display device according to an embodiment.

Referring to FIG. 4, the metal layer 200 may be formed by depositing and patterning metal on the substrate 110. Next, the buffer layer 120 is formed on the substrate 110 on which the metal layer 200 is formed, and a first oxide semiconductor layer is formed and patterned on the buffer layer 120 to form the first semiconductor layer 211 of the first transistor TR1. The first semiconductor layer 211 may be formed through wet etching.

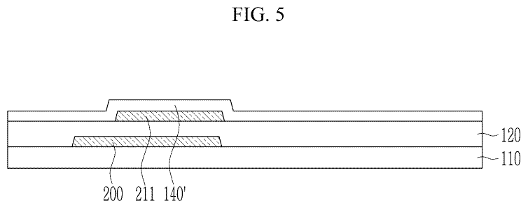

Referring to FIG. 5, an insulating material may be deposited on the first semiconductor layer 211 and the buffer layer 120 to form a preliminary lower gate insulating layer 140′. The insulating material may be an inorganic insulating material or an organic insulating material. For example, the insulating material may include silicon oxide (SiOₓ). The preliminary lower gate insulating layer 140′ may be formed to entirely cover the first semiconductor layer 211.

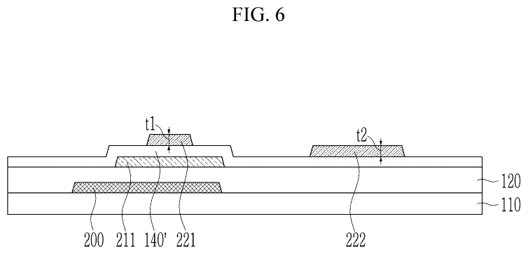

Referring to FIG. 6, a lower gate electrode may be formed on the preliminary lower gate insulating layer 140′. The first lower gate electrode 221 and the second lower gate electrode 222 may be formed of the same material in the same process. For example, a conductive layer may be formed by depositing a metal, a metal alloy, etc. on the preliminary lower gate insulating layer 140′, and the conductive layer may be patterned to form a lower gate electrode including the first lower gate electrode 221 overlapping the first semiconductor layer 211 and the second lower gate electrode 222 spaced apart from the first lower gate electrode 221 in a plan view.

A metal, a metal alloy, or the like may be deposited on the preliminary lower gate insulating layer 140′ so that the lower gate electrode has a thickness of 2,000 Å or less, about 1,500 Å or less, or about 1,000 Å or less. Additionally, a metal, a metal alloy, or the like may be deposited on the preliminary lower gate insulating layer 140′ so that the lower gate electrode has a thickness of 100 Å or more, about 300 Å or more, or about 500 Å or more.

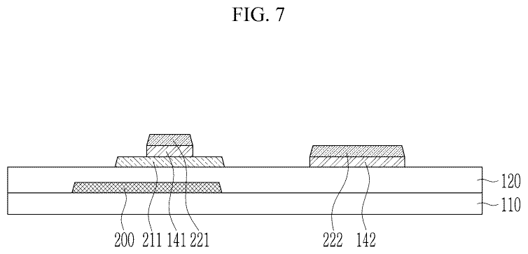

Referring to FIG. 7, the preliminary lower gate insulating layer 140′ may be etched to form a lower gate insulating layer including the first lower gate insulating layer 141 and the second lower gate insulating layer 142. The preliminary lower gate insulating layer 140′ may be dry etched.

The first lower gate insulating layer 141 and the second lower gate insulating layer 142 may be formed to have substantially the same width or planar shape as the first lower gate electrode 221 and the second lower gate electrode 222, respectively. For example, the first lower gate electrode 221 and the second lower gate electrode 222 may be formed using a photoresist and a mask, and the preliminary lower gate insulating layer 140′ may be patterned using the mask of the first lower gate electrode 221 and the second lower gate electrode 222 to form the first lower gate insulating layer 141 and the second lower gate insulating layer 142.

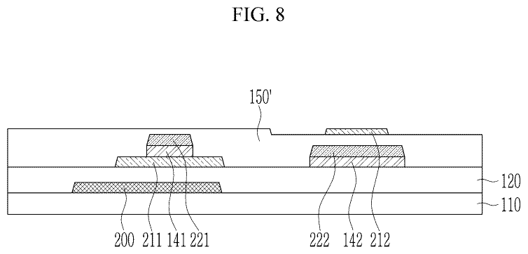

Referring to FIG. 8, an insulating material may be deposited on the first lower gate electrode 221 and the second lower gate electrode 222 to form a preliminary insulating layer 150′. The insulating material may include an inorganic insulating material, such as silicon oxide (SiOₓ). The preliminary insulating layer 150′ may be formed to cover all of the first lower gate electrode 221, the second lower gate electrode 222, the first lower gate insulating layer 141, the second lower gate insulating layer 142, and the first semiconductor layer 211. The preliminary insulating layer 150′ may have a structure of two or fewer layers. Accordingly, the thickness of the preliminary insulating layer 150′ may be reduced.

The preliminary insulating layers 150′ may be deposited to have a step difference between them. The preliminary insulating layer 150′ on the first lower gate electrode 221 may be deposited to be higher from the buffer layer 120 than the preliminary insulating layer 150′ on the second lower gate electrode 222. Accordingly, even if the second semiconductor layer 212 is formed on the preliminary insulating layer 150′, the first upper gate insulating layer 143 and the second upper gate insulating layer 144 may be formed at the same level, and the first upper gate electrode 231 and the second upper gate electrode 232 may be formed at the same level. Thus, the process difficulty of the deposition process of the upper gate insulating layer and the upper gate electrode 230 may be reduced.

The second semiconductor layer 212 of the second transistor TR2 may be formed on the preliminary insulating layer 150′. An oxide semiconductor may be deposited on the preliminary insulating layer 150′ to form a second oxide semiconductor layer and patterned to form the second semiconductor layer 212. The second semiconductor layer 212 may be patterned through wet etching.

The first transistor TR1 including the first semiconductor layer 211 may be provided as a switching transistor, and the second transistor TR2 including the second semiconductor layer 212 may be provided as a driving transistor. Therefore, the oxide semiconductor of the first semiconductor layer 211 and the oxide semiconductor of the second semiconductor layer 212 may include different materials from each other. The oxide semiconductor of the first semiconductor layer 211 may include copper oxide (CuO), titanium oxide (TiO₂), indium-tin-gallium-zinc oxide (ITGZO), etc., which may withstand high voltage and current. The oxide semiconductor of the second semiconductor layer 212 may include indium-tin oxide (ITO), zinc oxide (ZnO), indium-gallium-zinc oxide (IGZO), etc., which may have high electron mobility.

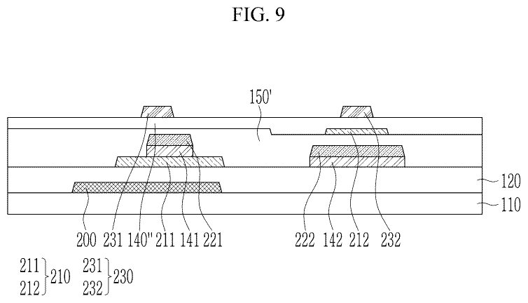

Referring to FIG. 9, an insulating material may be deposited on the preliminary insulating layer 150′ and the second semiconductor layer 212 to form a preliminary upper gate insulating layer 140″. The insulating material may be an inorganic insulating material or an organic insulating material. For example, the insulating material may include silicon oxide (SiOₓ). The preliminary upper gate insulating layer 140″ may be formed to entirely cover the second semiconductor layer 212.

The upper gate electrode 230 may be formed on the preliminary upper gate insulating layer 140″. The first upper gate electrode 231 and the second upper gate electrode 232 may be formed of the same material in the same process. For example, a metal, a metal alloy, etc. may be deposited on the preliminary upper gate insulating layer 140″. The upper gate electrode 230 including the first upper gate electrode 231 overlapping the first semiconductor layer 211 and the second upper gate electrode 232 overlapping the second semiconductor layer 212 in a plan view may be formed by patterning a deposited metal, a metal alloy, etc. The first upper gate electrode 231 and the second upper gate electrode 232 may be patterned to be separated from each other.

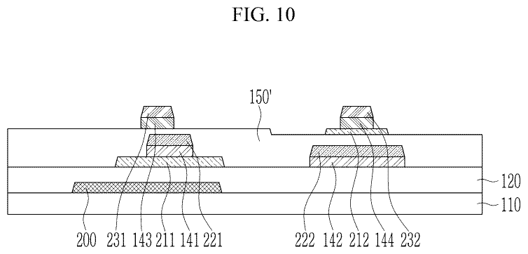

Referring to FIG. 10, the preliminary upper gate insulating layer 140″ may be etched to form an upper gate insulating layer including the first upper gate insulating layer 143 and the second upper gate insulating layer 144. The preliminary upper gate insulating layer 140″ may be etched through dry etching.

The first upper gate insulating layer 143 and the second upper gate insulating layer 144 may be formed to have substantially the same width or planar shape as the first upper gate electrode 231 and the second upper gate electrode 232, respectively. For example, the first upper gate electrode 231 and the second upper gate electrode 232 may be formed using a photoresist and a mask overlapping the first upper gate electrode 231 and the second upper gate electrode 232 in a plan view, and the preliminary upper gate insulating layer 140″ may be patterned using the mask of the first upper gate electrode 231 and the second upper gate electrode 232 to form the first upper gate insulating layer 143 and the second upper gate insulating layer 144.

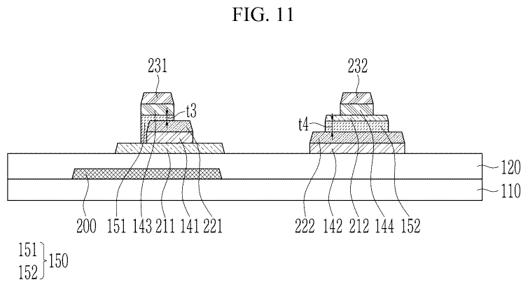

Referring to FIG. 11, the preliminary insulating layer 150′ may be etched to form the insulating layer 150 including the first insulating layer 151 and the second insulating layer 152 that are separated from each other. The first insulating layer 151 and the second insulating layer 152 may be formed of the same material in the same process. As described with reference to FIG. 8, the preliminary insulating layer 150′ may be formed on the first lower gate electrode 221 and the second lower gate electrode 222, and the preliminary insulating layer 150′ may be etched to form the first insulating layer 151 and the second insulating layer 152 together. The preliminary insulating layer 150′ may be etched through dry etching. For example, the first upper gate electrode 231 and the second upper gate electrode 232 may be formed using a photoresist and a mask overlapping the first upper gate electrode 231 and the second upper gate electrode 232 in a plan view, and the preliminary insulating layer 150′ may be patterned using the mask of the first upper gate electrode 231 and the second upper gate electrode 232 to form the first insulating layer 151 and the second insulating layer 152. The mask for patterning the preliminary insulating layer 150′ may be a mask having the same planar shape as the mask for patterning the first upper gate insulating layer 143 and the second upper gate insulating layer 144 described with reference to FIG. 10.

Referring to FIG. 11, it is stated that the preliminary insulating layer 150′ is etched to form the first insulating layer 151 and the second insulating layer 152 that are separated from each other, but the preliminary insulating layer 150′ may not be etched. For example, with reference to FIG. 8, a preliminary insulating layer 150′ formed by depositing an insulating material on the first lower gate electrode 221 and the second lower gate electrode 222 as described above may be used as the first insulating layer and the second insulating layer connected to each other.

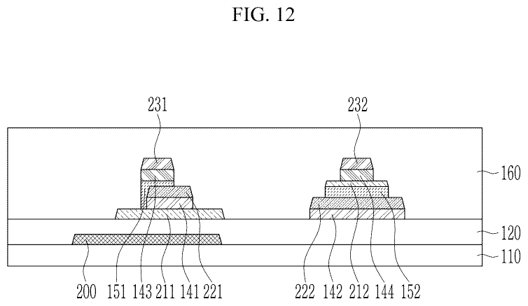

Referring to FIG. 12, an insulating material may be deposited on the first upper gate electrode 231 and the second upper gate electrode 232 to form the interlayer-insulating layer 160. The insulating material may be an inorganic insulating material or an organic insulating material. For example, the insulating material included in the interlayer-insulating layer 160 may include at least one of silicon nitride (SiNₓ) or silicon oxide (SiOₓ). The interlayer-insulating layer 160 may be formed as a single-layer structure or a multi-layer structure including silicon nitride (SiNₓ) and silicon oxide (SiOₓ).

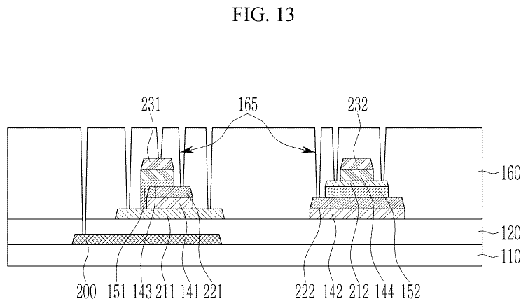

Referring to FIG. 13, an interlayer contact hole 165 may be formed in the interlayer-insulating layer 160. The interlayer contact hole 165 may overlap the metal layer 200, the first semiconductor layer 211, the second semiconductor layer 212, the first lower gate electrode 221, the second lower gate electrode 222, and the first upper gate electrode 231 in a plan view. The interlayer contact hole 165 may be formed through dry etching. For example, the interlayer contact hole 165 may be formed by patterning the interlayer-insulating layer 160 using a mask having an opening overlapping the interlayer contact hole 165 in a plan view.

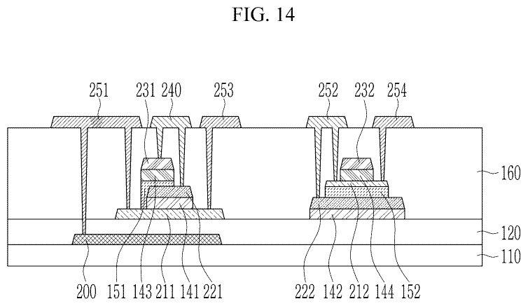

Referring to FIG. 14, the connector 240 overlapping the interlayer contact hole 165, the first electrode 251 and the second electrode 253 of the first transistor TR1, and the first electrode 252 and the second electrode 254 of the second transistor TR2 in a plan view may be formed. A conductive material such as a metal may be deposited and patterned to fill the interlayer contact hole 165 on the interlayer-insulating layer 160, thereby forming the connector 240, the first electrode 251 and the second electrode 253 of the first transistor TR1, and the first electrode 252 and the second electrode 254 of the second transistor TR2.

The connector 240 may be formed to electrically connect the first lower gate electrode 221 and the first upper gate electrode 231. A conductive material filling the interlayer contact hole 165 overlapping the first lower gate electrode 221 and the interlayer contact hole 165 overlapping the first upper gate electrode 231 in a plan view may be patterned to be connected on the interlayer-insulating layer 160. Accordingly, the connector 240 that electrically connects the first lower gate electrode 221 and the first upper gate electrode 231 may be formed.

The first electrode 252 of the second transistor TR2 may be formed to electrically connect the second lower gate electrode 222 and the second semiconductor layer 212. The conductive material filling the interlayer contact hole 165 overlapping the second lower gate electrode 222 and the interlayer contact hole 165 overlapping the second upper gate electrode 232 in a plan view may be patterned to be connected on the interlayer-insulating layer 160. Accordingly, the first electrode 252 of the second transistor TR2 electrically connecting the second lower gate electrode 222 and the second semiconductor layer 212 may be formed.

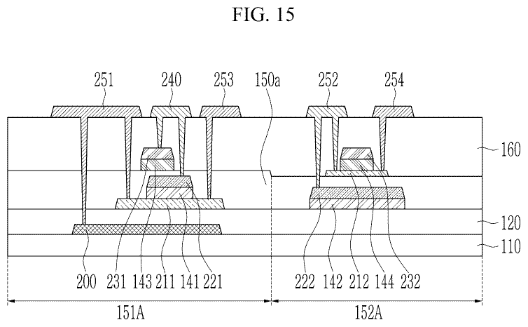

FIG. 15 is a cross-sectional view of a display device according to an embodiment. The cross-section shown in FIG. 2 may correspond to a backplane of an area corresponding to approximately one pixel area. In describing FIG. 15, the contents described with reference to FIG. 2 will be omitted.

Referring to FIG. 15, the first insulating layer 151 and the second insulating layer 152 may be connected to each other. The first insulating layer 151 and the second insulating layer 152 may be connected to each other and positioned as one insulating layer 150a on the first lower gate electrode 221 and the second lower gate electrode 222. The insulating layer 150a may cover the edge of the first semiconductor layer 211.

The insulating layer 150a may be divided into a first insulating layer portion 151A and a second insulating layer portion 152A having different heights. There may be a step at the boundary between the first insulating layer portion 151A and the second insulating layer portion 152A. The height from the buffer layer 120 of the first insulating layer portion 151A may be greater than the height from the buffer layer 120 of the second insulating layer portion 152A. Accordingly, even if the second semiconductor layer 212 is positioned on the second insulating layer portion 152A, the first upper gate insulating layer 143 and the second upper gate insulating layer 144 may be positioned at the same level. Additionally, the first upper gate electrode 231 and the second upper gate electrode 232 may be positioned at the same level.

The thickness of the insulating layer 150a from the first lower gate electrode 221 in the first insulating layer portion 151A of the insulating layer 150a and the thickness of the insulating layer 150a from the second lower gate electrode 222 in the second insulating layer portion 152A of the insulating layer 150a may be 1,000 Å or less, 900 Å or less, or 800 Å or less. Additionally, the thickness of the insulating layer 150a from the first lower gate electrode 221 in the first insulating layer portion 151A of the insulating layer 150a and the thickness of the insulating layer 150a from the second lower gate electrode 222 in the second insulating layer portion 152A of the insulating layer 150a may be 100 Å or more, 200 Å or more, or 300 Å or more. Accordingly, the size of the transistors TR1 and TR2 may be reduced, and the on-resistance may be reduced, thereby improving the efficiency of the transistors TR1 and TR2. In addition, damage and electrical leakage caused by the excessively thin thicknesses of the first insulating layer 151 and the second insulating layer 152 may be prevented.

The first lower gate electrode 221 and the first upper gate electrode 231 may be electrically connected through the connector 240. Additionally, the second lower gate electrode 222 and the second semiconductor layer 212 may be electrically connected through the first electrode 252 of the second transistor TR2. Accordingly, even if the first lower gate electrode 221 and the second lower gate electrode 222 are formed thinly, surface resistance may be reduced.

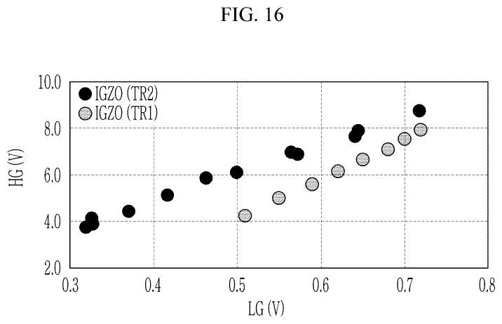

FIG. 16 is a graph showing voltage relationships in two different frequency ranges of the display device according to an embodiment. Specifically, the voltage relationship at a low grayscale DR3 and a high grayscale DR is shown when the first semiconductor layer of the switching transistor corresponding to the first transistor TR1 and the second semiconductor layer of the driving transistor corresponding to the second transistor TR2 include IGZO.

Referring to FIG. 16, it can be seen that the first transistor TR1 including the first lower gate electrode with a thin thickness (e.g., 1,000 Å or less) and the second transistor TR2 including the second lower gate electrode with a thin thickness (e.g., 1,000 Å or less) have small voltage changes at the high grayscale HG even when there is a voltage change at the low grayscale LG over a wide range.

Depending on the voltage, various colors may be expressed at the low grayscale LG. If the voltage change at the high grayscale HG is large due to the voltage change at the low grayscale LG, it may be difficult to precisely control the color of the low grayscale LG that requires relatively low voltage. However, as shown in FIG. 16, it can be seen that the voltage change at the high grayscale HG is small even at the low grayscale LG in a wide range. Therefore, it may be seen that various low grayscale LG colors may be expressed by using the first lower gate electrode with a thin thickness and the second lower gate electrode with a thin thickness.

The above-described display device may be applied to various electronic devices. An electronic device according to an embodiment may include an electronic component and the above-described display device. The display device may include a substrate and a first transistor and a second transistor positioned on the substrate. The first transistor may include a first semiconductor layer, a first lower gate electrode positioned on the first semiconductor layer, a first insulating layer positioned on the first lower gate electrode, and a first upper gate electrode positioned on the first insulating layer. The second transistor may include a second lower gate electrode, a second insulating layer positioned on the second lower gate electrode, a second semiconductor layer positioned on the second insulating layer, and a second upper gate electrode positioned on the second semiconductor layer. An electronic device may further include modules or devices having additional functions other than the display device.

The display device according to the embodiments may be applied to various electronic devices. The electronic device according to an embodiment includes the above-described display device, and may further include a module or device having additional functions other than the display device.

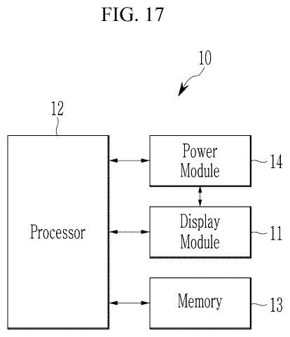

FIG. 17 is a block diagram of an electronic device according to an embodiment.

Referring to FIG. 17, the electronic device 10 may include a display module 11, a processor 12, memory 13, a power module 14, and the like.

The display module 11 may include a display panel, a driver, etc. The display panel may include pixels that display an image and may provide a display screen. The driver may process signals and supply them to the display panel to display an image on the display screen of the display panel. The driver may be provided in the form of an integrated circuit chip.

The processor 12 may include at least one of a central processing unit (CPU), an application processor (AP), a graphic processing unit (GPU), a communication processor (CP), an image signal processor (ISP), or a controller.

Data information necessary for the operation of the processor 12 or the display module 11 may be stored in a memory 15. When the processor 12 executes an application stored in the memory 15, an image data signal and/or an input control signal is transmitted to the display module 11, and the display module 11 may process the received signal and display an image through the display screen.

The power module 14 may include a power supply module, such as a power adapter or a battery device, and a power conversion module that converts power supplied by the power supply module to generate power required for the operation of the electronic device 10.

At least one of the components of the electronic device 10 described above may be included in the display device according to the embodiments. Additionally, some of the individual modules functionally included within a module may be included within the display device, while others may be provided separately from the display device. For example, the display device may include the display module 11, and the processor 12, the memory 13 and the power module 14 may be provided in the form of devices within the electronic device 10 other than the display device.

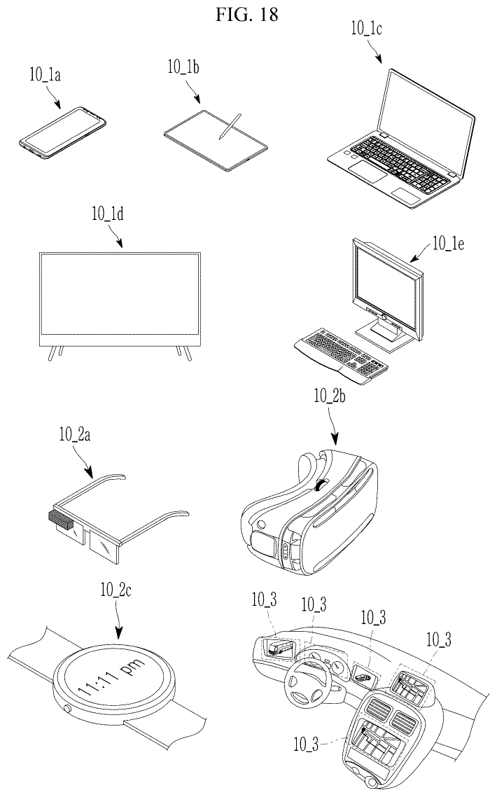

FIG. 18 is a schematic diagram of an electronic device according to various embodiments.

Referring to FIG. 18, various electronic devices to which display devices according to the embodiments are applied may include electronic devices for displaying images, such as a smartphone 10_1a, a tablet PC 10_1b, a laptop 10_1c, a TV 10_1d, and a desk monitor 10_1e. In addition, the electronic device may include a wearable electronic device including a display module such as smart glasses 10_2a, a head mounted display 10_2b, a smartwatch 10_2c, and the like, a vehicle electronic device 10_3 including a display module or display device such as a center information display (CID), a room mirror display, and the like disposed on a dashboard, a center fascia, or an instrument panel of an automobile, and the like.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A display device, comprising:
a substrate; and
a first transistor and a second transistor, which are disposed on the substrate,
wherein the first transistor comprises:
a first semiconductor layer;
a first lower gate electrode disposed on the first semiconductor layer;
a first insulating layer disposed on the first lower gate electrode; and
a first upper gate electrode disposed on the first insulating layer, and
wherein the second transistor comprises:
a second lower gate electrode;
a second insulating layer disposed on the second lower gate electrode;
a second semiconductor layer disposed on the second insulating layer; and
a second upper gate electrode disposed on the second semiconductor layer.

2. The display device of claim 1, wherein
the first transistor and the second transistor are spaced apart from each other, and
the first insulating layer and the second insulating layer are separated from each other.

3. The display device of claim 1, further comprising:
a first connector electrically connecting the first lower gate electrode and the first upper gate electrode.

4. The display device of claim 1, further comprising
a second connector electrically connecting the second lower gate electrode and the second semiconductor layer.

5. The display device of claim 1, further comprising
a metal layer disposed between the substrate and the first semiconductor layer and overlapping the first lower gate electrode in a plan view.

6. The display device of claim 1, wherein
a thickness of the first insulating layer from a top surface of the first lower gate electrode and a thickness of the second insulating layer from a top surface of the second lower gate electrode are each 100 to 1,000 angstroms (Å), and
the first lower gate electrode and the second lower gate electrode each have a thickness of 100 to 2,000 Å.

7. The display device of claim 1, wherein
the first lower gate electrode and the second lower gate electrode include at least one of molybdenum or titanium.

8. The display device of claim 1, wherein
the first insulating layer and the second insulating layer include silicon oxide.

9. The display device of claim 1, wherein
the first semiconductor layer and the second semiconductor layer include different oxide semiconductors.

10. The display device of claim 1, further comprising:
a first lower gate insulating layer disposed between the first semiconductor layer and the first lower gate electrode;
a first upper gate insulating layer disposed between the first insulating layer and the first upper gate electrode;
a second lower gate insulating layer disposed between the substrate and the second lower gate electrode; and
a second upper gate insulating layer disposed between the second semiconductor layer and the second upper gate electrode.

11. The display device of claim 1, wherein
the first insulating layer and the second insulating layer are connected to each other.

12. The display device of claim 11, further comprising:
a first connector electrically connecting the first lower gate electrode and the first upper gate electrode; and
a second connector electrically connecting the second lower gate electrode and the second semiconductor layer.

13. The display device of claim 11, further comprising
a metal layer disposed between the substrate and the first semiconductor layer and overlapping the first semiconductor layer in a plan view.

14. The display device of claim 11, wherein
a thickness of the first insulating layer from a top surface of the first lower gate electrode and a thickness of the second insulating layer from a top surface of the second lower gate electrode are each 100 to 1,000 Å, and
a first lower gate electrode and the second lower gate electrode each have a thickness of 100 to 2,000 Å.

15. An electronic device, comprising
an electronic component; and
a display device,
wherein the display device comprises:
a substrate; and
a first transistor and a second transistor, which are disposed on the substrate,
wherein the first transistor comprises:
a first semiconductor layer;
a first lower gate electrode disposed on the first semiconductor layer;
a first insulating layer disposed on the first lower gate electrode; and
a first upper gate electrode disposed on the first insulating layer, and
wherein the second transistor comprises
a second lower gate electrode;
a second insulating layer disposed on the second lower gate electrode;
a second semiconductor layer disposed on the second insulating layer; and
a second upper gate electrode disposed on the second semiconductor layer.

16. A method for manufacturing a display device, comprising:
forming a first transistor on a substrate; and
forming a second transistor on the substrate,
wherein the forming of the first transistor comprises:
forming a first semiconductor layer on the substrate;
forming a first lower gate electrode on the first semiconductor layer;
forming a first insulating layer on the first lower gate electrode; and
forming a first upper gate electrode on the first insulating layer, and
wherein the forming of the second transistor comprises:
forming a second lower gate electrode on the substrate;
forming a second insulating layer on the second lower gate electrode;
forming a second semiconductor layer on the second insulating layer; and
forming a second upper gate electrode on the second semiconductor layer.

17. The method for manufacturing the display device of claim 16, wherein
the first lower gate electrode and the second lower gate electrode are formed of a same material in a same process,
the first insulating layer and the second insulating layer are formed of a same material in a same process, and
the first upper gate electrode and the second upper gate electrode are formed of a same material in a same process.

18. The method for manufacturing the display device of claim 16, wherein
forming the first insulating layer and the second insulating layer comprises
depositing an insulating material on the first lower gate electrode and the second lower gate electrode to form a preliminary insulating layer; and
etching the preliminary insulating layer to form the first insulating layer and the second insulating layer, which are separated from each other.

19. The method for manufacturing the display device of claim 16, wherein
forming the first insulating layer and the second insulating layer comprises:
depositing an insulating material on the first lower gate electrode and the second lower gate electrode to form the first insulating layer and the second insulating layer connected to each other.

20. The method for manufacturing the display device of claim 16, further comprising:
forming a first connector electrically connecting the first lower gate electrode and the first upper gate electrode; and
forming a second connector electrically connecting the second lower gate electrode and the second semiconductor layer.
